(19) United States
(12) Patent Application Publication
(10) Pub. No.: US 2016/0312347 A1
(43) Pub. Date: Oct. 27, 2016

(54) MORPHOLINE BATH AND METHOD FOR CHEMICALLY DEPOSITING A LAYER

(71) Applicants: ELECTRICITE DE FRANCE, Paris (FR); CENTRE NATIONAL DE LA RECHERCHE SCIENTIFIQUE - CNRS -, Paris (FR)

(72) Inventors: Thibaud HILDEBRANDT, Tallard (FR); Negar NAGHAVI, Paris (FR); Nicolas LOONES, Nanterre (FR); Nathanaelle SCHNEIDER, Paris (FR)

(21) Appl. No.: 15/103,694

(22) PCT Filed: Feb. 12, 2015
(86) PCT No.: PCT/FR2015/050350

§ 371 Date: Jun. 10, 2016

(30) Foreign Application Priority Data
Dec. 12, 2013 (FR) 13 62539

(51) Int. Cl. C23C 2/04

(52) U.S. Cl. CPC C23C 2/04

(57) ABSTRACT

A chemical bath for depositing a layer made from at least metal and sulphur is described. Furthermore, a method for depositing such a layer is described. This bath comprises, in solution: a metal salt comprising a metal chosen from at least one of the elements from groups IIB and MA of the periodic table; and a sulphur precursor. The bath further comprises a morpholine compound.

### TECHNICAL FIELD

The invention relates to the field of chemical deposition baths for the deposition of layers based on sulfur and metal. It also relates to methods for chemically depositing a layer based on metal and sulfur.

### TECHNOLOGICAL BACKGROUND

Methods for Chemical Bath Deposition (CBD) are commonly used in industry, for example to fabricate alloys in thin layers (“thin films”). These methods are particularly suitable for large-scale deposition to cover large areas exceeding 60×30 cm². In addition, this technique is widely used in industry due to its low cost and its technical simplicity.

Chemical bath deposition can thus be considered in the fabrication of certain thin layers of photosensitive devices. More particularly, the absorber layers in some photosensitive devices are generally covered by a so-called “buffer” layer made of an alloy comprising metal and sulfur. Generally, this buffer layer consists of an alloy of cadmium sulfur CdS.

The toxicity of cadmium prompts us to look for alternative materials for the buffer layer, such as zinc sulfide ZnS and its derivatives. However, the deposition rate of these alloys on any surface, and particularly on other thin layers such as light absorbers, is not optimal. Obtaining a chemical deposition that meets industry requirements can involve times considered to be long, exceeding 15 minutes or even an hour. Such lengthening of the deposition time adds to manufacturing costs and penalizes the entire chain of production of a device.

For this reason, special attention is being paid to finding technical means for achieving the deposition of a layer based on at least sulfur and a metal, by CBD.

To reduce the deposition time of such a layer, it is known to increase either the concentration of reagents in the chemical bath or the temperature, or to preheat the reagents. However, these three means have the disadvantage of causing an increase in the consumption of materials and energy. They may also present the risk of damage to the deposition surface, or may involve additional steps in the chain of production of a type that incurs additional costs.

Another solution for accelerating the deposition rate is to use a specific sulfur precursor in a chemical bath. Generally, the chemical baths for depositing a layer of metal and sulfur make use of a thiourea solution as sulfur precursor. Document US2013/0084401 proposes replacing thiourea by thioacetamide. This alternative, however, has the disadvantage that thioacetamide is a highly toxic compound and is therefore not very suitable for an industrial application.

Another alternative suggested in document DE102009015063A1 consists in adding hydrogen peroxide H₂O₂ to a chemical bath provided for deposition of a thin layer based on sulfur and metal. This solution is not suitable for industrial applications where the deposition surface is fragile, given the corrosive nature of the H₂O₂ additive.

For these reasons, we seek a means for increasing the deposition rate in a chemical bath of a layer comprising at least sulfur and a metal, and which is compatible with a wide range of industrial applications.

### Disclosure of Invention

To address the problems described above, the present invention provides a chemical bath for depositing a layer based on at least metal and sulfur. This bath comprises, in solution:
a metal salt comprising a metal selected from among at least one of the elements of groups JIB and IIIA of the periodic table; and
a sulfur precursor.

This bath further comprises a morpholine compound.

A bath for the chemical deposition of a layer comprising sulfur and a metal from groups JIB or IIIA of the periodic table is thus optimized by adding a morpholine-type non-toxic organic additive into the bath solution mixture. The applicant has found that the addition of morpholine produces in the mixture an effect comparable to that of a reaction accelerator. The morpholine appears to interact with the sulfur precursor by promoting its hydrolysis, in the manner of a solution of basic pH such as ammonia. The presence of morpholine can thus accelerate the formation of the sulfur- and metal-based alloy on the deposition surface. Morpholine is an organic compound having both an amine function, provided by the presence of an —NH group (amine), and an ether function (—O—). The combination of these two functions can act on the ions of the metal salt, for example Zn²⁺, promoting their integration into complexes. These complexes are involved in the reaction that enables depositing the metal and the sulfur in the same layer. The morpholine thus acts in the bath as a complexing agent.

The increase in deposition rate seems to be particularly pronounced when the metal belongs to groups IIIA or IIB, such as zinc Zn or indium In for example.

In addition to increasing the deposition rate, the applicant has found that the addition of morpholine allows obtaining homogeneous metal- and sulfur-based layers on large surfaces. The addition of morpholine to the chemical bath thus allows obtaining a homogeneous deposition over a large surface area compared to CBD depositions involving baths without this additive.

Another advantageous effect obtained by the addition of morpholine lies in the fact that the deposition can be done without preheating the bath reagents. By eliminating a prior preheating step, it is possible to increase the production rate at the industrial scale. However, it is also possible to preheat the reagents, enabling the bath described above to easily be prepared in existing production lines.

The addition of morpholine to a chemical deposition bath has the further advantage of giving the reaction mixture of the bath a basic pH. With an acidity constant pKa of 8.5, morpholine can be considered in a bath containing no ammonia solution. The ammonia which is usually found in CBD deposition baths has the function of increasing the pH of a reaction mixture to promote hydrolysis of the compounds. This same function can advantageously be fulfilled by morpholine, reducing the amount of reagents used when preparing the bath.

These effects are independent of the surface on which the deposit is made. In particular, the optimized bath described above allows for example making deposits on glass, metal substrates, or semiconductors, as well as on compounds having photovoltaic properties such as absorbers.

These effects have been observed in different experimental configurations, and seem to occur regardless of the concentration of reagents in the chemical bath. However, a temperature below the denaturation threshold of one of the compounds of the reaction mixture is advantageously preferred.

According to one advantageous embodiment, the morpholine compound has an amine function and an ether function acting as a complexing agent in the bath.

The ether and amine functions of the morpholine are active groups in the morpholine compound used in the bath. These functions contribute to depositing the metal and the sulfur in the same layer by forming complexes with metal ions of other reagents of the bath, as explained above.

According to one advantageous embodiment, the compound may have the chemical formula C₄H₉NO.

This compound may advantageously be in a solution that is miscible with the other reagents of the chemical bath. It has been noted that the morpholine compound of chemical formula C₄H₉NO optimizes the deposition rate and the homogeneity of the obtained layer in a particularly visible manner. However, the active component of morpholine is also found in an extensive line of derivative molecules which also comprise an ether function and an amine function. Other morpholine-based compounds could therefore be envisaged.

According to one embodiment, a concentration between 0.001 mol/L and 10 mol/L of morpholine may be provided in the bath, for a concentration between 0.05 mol/L and 1 mol/L of sulfur compound.

Such a reaction mixture in the bath corresponds to a compromise between quantity of reagents used and rapidity of deposition. By keeping the amount of additive and of sulfur compound low, it is possible to achieve significant savings during production at an industrial scale. This is due to less waste of reagents.

Advantageously, the solution containing the metal salt may be a solution selected from among: zinc sulfate, zinc acetate, and zinc chloride, at a concentration between 0.01 mol/L and 1 mol/L.

The metal salt may include other metals from groups IIB and IIIA of the periodic table. However, a zinc metal salt in the bath provided a particularly pronounced reduction of the deposition time. In comparison to CBD deposition in a bath without morpholine and using a zinc metal salt, the invention achieves a deposition rate which is up to four times higher.

A concentration between 0.01 mol/L and 1 mol/L of metal salt allows reducing the amount of raw material used to deposit the layer.

According to one embodiment, the bath may further comprise an ammonia solution at a concentration of less than 10 mol/L.

The use of an ammonia solution gives a basic pH to the chemical bath, in order to initiate hydrolysis of the sulfur precursor so that it reacts with the metal salt.

According to one embodiment, the bath may not contain any ammonia solution.

Given the naturally basic character of morpholine in solution, it is possible not to add ammonia to the chemical bath. In this manner, the invention allows reducing the amount of reagents used when preparing the bath. It turns out that morpholine is an effective substitute for ammonia, despite an acidity constant pKa of 8.5 which is lower by 0.75 than the acidity constant of ammonia.

According to one embodiment, the solution containing the sulfur compound may be a solution of thiourea CS(NH₂)₂.

Thiourea is a sulfur precursor that is particularly suitable for the deposition of layers comprising sulfide. It is commonly used in the photosensitive devices industry, for example.

Thiourea enables particularly rapid deposition in the presence of morpholine and of a metal salt. The deposition rates obtained when thiourea is used can thus be less than 5 minutes for a layer of metal sulfide or oxysulfide that is 20 nm thick.

More particularly, the metal may be an element from column IIB.

Metals of column JIB are of particular interest to the photosensitive devices industry. In these devices, metals such as cadmium or zinc may be present in the buffer layer between the absorber and the front electrical contact of a photosensitive cell. Elements of column IIB are therefore particularly suitable for a chemical bath intended for the creation of buffer layers.

In one particular embodiment, the metal may be zinc.

Deposition of a zinc sulfide or oxysulfide layer by CBD is of interest for example in the photosensitive devices industry due to its optical properties and non-toxicity. A layer made of such an alloy is an effective and non-toxic alternative to buffer layers of CdS, while allowing the transmission of more radiation of wavelengths below 500 nm.

A layer of zinc sulfide or oxysulfide has a higher energy band gap than a CdS layer, therefore transmitting more light at wavelengths below 500 nm than a CdS layer. In addition, a layer of zinc sulfide or oxysulfide has optical transmission properties equivalent to those of layers of zinc oxide ZnO, which are often used to form the front electrical contacts of photosensitive devices.

The invention also relates to a method for chemically depositing a layer based on at least metal and sulfur, in a bath comprising, in solution:
a metal salt comprising a metal selected from among at least one of the elements of groups IIB and IIIA of the periodic table; and
a sulfur precursor.

In addition, a morpholine compound is provided in the bath.

CBD deposition of a layer based on at least metal and sulfur with the addition of morpholine in the chemical bath offers several advantages, described above. The addition of morpholine in the bath increases the deposition rate, allows achieving more homogeneous layers, and can save preparation time due to the possibility of eliminating an earlier step of preheating the chemical bath reagents.

In one particular embodiment, the layer may be based on a metal sulfide.

The metal sulfide, for example ZnS, may be an alloy particularly suitable for applications in photosensitive devices. For example, it may be used as a buffer layer on absorbers of photosensitive devices.

In another embodiment, the layer may be based on a metal oxysulfide.

Metal oxysulfides, for example Zn(S,O), Zn(S,O,OH), or Inₓ(S,O)_{y}, Inₓ(S,O,OH)_{y}, where 0<x<2 and 0<y<3, can have optical properties that are particularly suitable for the requirements of the photosensitive devices industry. They may also be suitable for use as buffer layers on a photosensitive layer.

Advantageously, the bath temperature during deposition may be between 40° C. and 100° C.

A deposition temperature below 100° C. and in particular below 70° C. allows a work environment that is less damaging to devices comprising alloys having a low melting point, without being penalized by an increase in the deposition duration. In addition, by reducing the temperature of the reaction medium, it is possible to save energy due to less heating of the CBD deposition bath. These savings increase with the size of the bath, which can reach several square meters at the industrial scale.

According to one embodiment, the layer based on metal and sulfur may be deposited on a layer having photovoltaic properties, said layer having photovoltaic properties forming the absorber of a thin-film solar cell.

In this manner, the layer based on metal and sulfur can represent a buffer layer deposited on an absorber of a thin-film photovoltaic cell, to interface the absorber with a front electrical contact. The quality of the interface between the absorber of a photosensitive cell and the buffer layer is crucial to achieving high conversion efficiency in the resulting device. Applying the chemical deposition method described above to the deposition of a buffer layer on an absorber yields homogeneous layers, having half as many defects as buffer layers deposited in a bath containing no morpholine, deposited in less than 10 minutes and without damaging the absorber itself.

Due to the quality of the buffer layer obtained by implementing the method, the resulting photovoltaic device can have a conversion efficiency exceeding 14%.

It should be noted that using morpholine as an additive in a chemical bath for the deposition of a buffer layer on a photovoltaic cell absorber is counterintuitive. Indeed, morpholine is generally used in the rubber industry or for the synthesis of drugs and agrochemicals.

The absorber may be based on a chalcopyrite compound among Cu(In,Ga)(S,Se)₂, Cu₂(Zn,Sn)(S,Se)₄, and their derivatives.

These compounds may include, for example, Cu(In,Ga)Se₂, CuInSe₂, CuInS₂, CuGaSe₂, Cu₂(Zn,Sn)S₄, and Cu₂(Zn,Sn)Se₄. When these absorbers contain zinc and tin, these compounds are sometimes called CZTS.

The solar cell absorbers listed above correspond to absorbers of CIGS and CZTS thin-film cells and their derivatives having conversion efficiencies that can exceed 20%. Making use of the method described above for depositing a buffer layer on these absorbers is particularly advantageous given the performance gains this provides. For example, by thus depositing a buffer layer of ZnS, Zn(S,O), or Zn(S,O,OH) on an absorber based on a chalcopyrite compound, it is possible to obtain a conversion efficiency exceeding 14% and an open circuit voltage and short-circuit current of the end device that are greater than those observed in devices obtained by other deposition methods.

### DESCRIPTION OF FIGURES

The method of the invention will be better understood by reading the following description of some exemplary embodiments presented for illustrative purposes but in no way limiting, and from observing the following drawings in which:

FIG. 1 is a schematic representation of a sample that is to receive the deposition of a layer of metal and sulfur; and

FIG. 2 is a schematic representation of the procedure for preparing a chemical bath; and

FIG. 3 is a graph comparing the measured deposition times to obtain different layer thicknesses by three different processes; and

FIG. 4 is a schematic representation of a photosensitive device; and

FIG. 5 is a graph comparing the quantum efficiencies of two layers made of different materials, as a function of the wavelength received.

For the sake of clarity, the dimensions of the various elements represented in these figures are not necessarily in proportion to their actual dimensions. In the figures, identical references correspond to identical elements.

### DETAILED DESCRIPTION

The invention relates to an improved chemical deposition bath and an improved CBD deposition method. The improvement aims in particular to significantly increase the deposition rate. Other advantageous effects have also been obtained in the context of the invention, such as increased deposition quality for example.

In the embodiments given below by way of example, the particular case of deposition by CBD of a buffer layer on a photovoltaic cell absorber will be described. However, the invention can also be applied to deposition on any other type of surface, as will be restated further below.

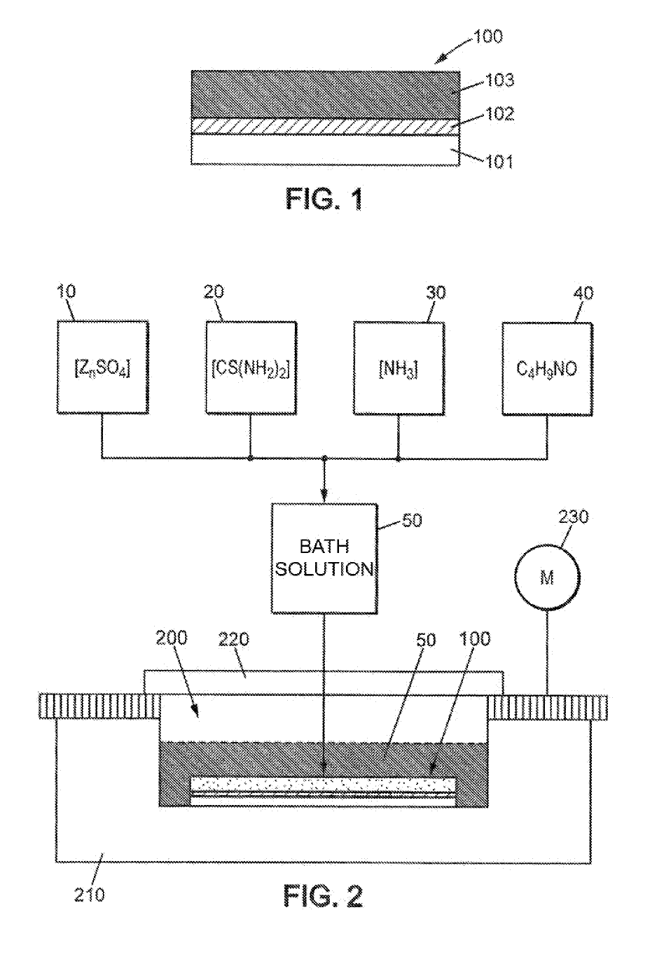

In the context of depositing a thin layer comprising at least sulfur and a metal, FIG. 1 illustrates an example of an initial sample 100, comprising a substrate 101, a rear metal contact 102, and an absorber layer 103. The initial sample 100 shown therefore represents an unfinished portion of a thin-film photosensitive device. As an example, the absorber 103 intended to convert radiation into current may be a chalcopyrite compound such as one of the compounds among Cu(In,Ga)(S,Se)₂, Cu₂(Zn,Sn)(S,Se)₄, and their derivatives. These derivatives may include, for example, Cu(In,Ga)Se₂, CuInSe₂, CuInS₂, CuGaSe₂, Cu₂(Zn,Sn)S₄, or Cu₂(Zn,Sn)Se₄, more commonly called CIGS and CZTS.

In order to complete the fabrication of this photosensitive device, the invention proposes a chamber 200 for the chemical bath, schematically represented in FIG. 2. As in most chemical baths for CBD deposition, the chamber 200 may be closed by a cover 220. This chamber 200 contains a solution 50 consisting of a mixture of reagents in the chosen concentrations. The sample 100 rests in this solution 50. Means for heating this reaction medium may be provided. In FIG. 2, such a means is represented by a water bath 210 surrounding the chamber containing the reaction medium. A motor 230 may also be used to drive a stirring mechanism that stirs the solution 50.

FIG. 2 also shows a summary of the steps for obtaining the solution forming the reaction mixture 50.

In the example illustrated in FIG. 2, the chemical bath is configured for deposition of a buffer layer of a photovoltaic device. For this reason, it is prepared from a first aqueous solution comprising a metal salt 10, represented as being zinc sulfate ZnSO₄. A second aqueous solution comprising a sulfur precursor 20 is also provided. This second solution is represented as being thiourea, of chemical formula CS(NH₂)₂. Ammonia 30, to give the reaction mixture a basic pH, may also optionally be provided. A medium that is basic due to the presence of ammonia promotes the reaction of the precursor with the metal salt. Finally, a fourth aqueous solution comprising a morpholine-based organic additive 40 is prepared. This fourth solution 40 is represented as comprising morpholine of chemical formula C₄H₉NO.

Alternatives to the first three solutions can be envisaged, as will be described below.

These four solutions 10, 20, 30, 40, are then mixed to create a reaction mixture 50. The reaction mixture 50 is the solution into which the sample 100 is dipped.

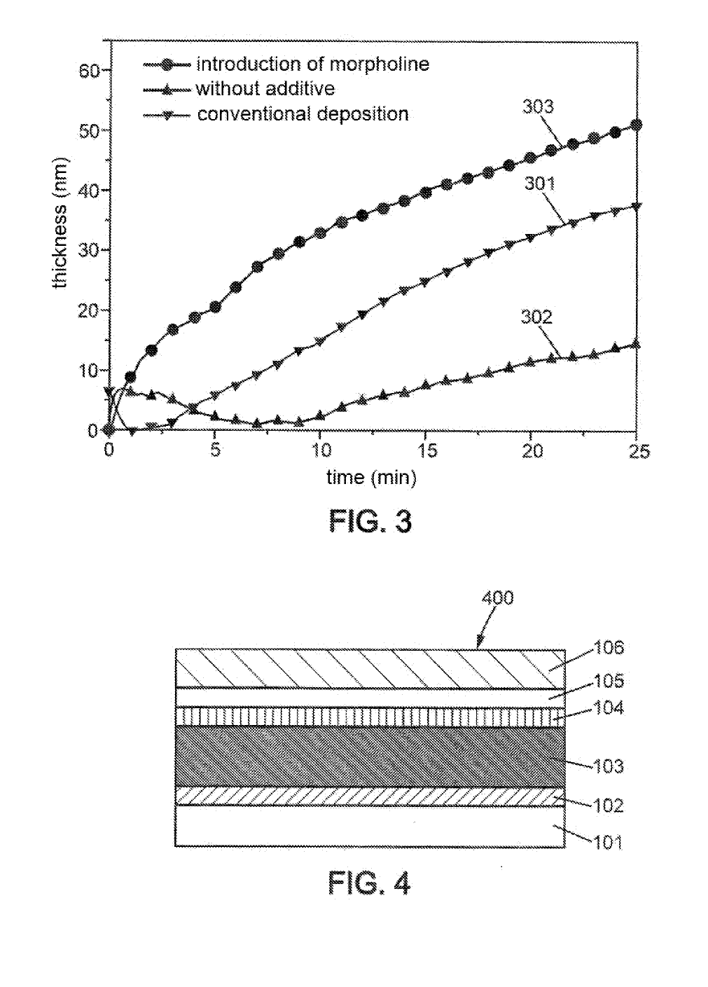

Advantageously, the addition of morpholine significantly reduces the time required to achieve deposition of ZnS on the absorber. To illustrate the time saved, the graph of FIG. 3 compares the rates of deposition of a thin layer by CBD, measured under three different conditions.

The deposited ZnS layer may include oxygen and form a layer of Zn(S,O) or Zn(S,O,OH) type. “ZnS layer” will be used hereinafter to refer to a layer of pure ZnS as well as to a layer of Zn(S,O) or Zn(S,O,OH).

Curve 301 shows the time required to deposit ZnS layers of different thicknesses, when the reaction mixture 50 is in a conventional configuration. “Conventional” is understood to mean a thiourea concentration of 0.65 mol/L, a ZnSO₄ concentration of 0.15 mol/L, and an ammonia concentration of 2 mol/L. The reagents were all preheated to a temperature of 80° C. before being placed in a chamber brought to the same temperature of 80° C.

Curve 302 represents the time required to deposit ZnS layers of different thicknesses, when the reaction mixture 50 comprises a laboratory-tested configuration corresponding to a particularly advantageous embodiment. It is characterized by a thiourea concentration of 0.4 mol/L, a ZnSO₄ concentration of 0.1 mol/L, and an ammonia concentration of 2 mol/L. No preheating of the reagents is provided and the deposition temperature is 70° C.

Curve 303 represents the time required to deposit ZnS layers of different thicknesses, when the reaction mixture 50 comprises the same characteristics as those associated with curve 302, but with the addition of a concentration of 2.2 mol/L morpholine. Table 1 below summarizes the three configurations described above.

TABLE 1
Summary of the three deposition configurations represented in FIG. 3

| | Thiourea | ZnSO₄ | NH₃ | C₄H₉NO | Deposition |
|---|---|---|---|---|---|
| ZnS layer | (mol/L) | (mol/L) | (mol/L) | (mol/L) | T (° C.) |
| Conventional | 0.65 | 0.15 | 2 | | 80 |
| deposition | | | | | |
| With | 0.4 | 0.1 | 2 | 2.2 | 70 |
| additive | | | | | |
| Without | 0.4 | 0.1 | 2 | | 70 |
| additive | | | | | |

It is apparent from the evolution of the three curves 301, 302, and 303 of FIG. 3, that the addition of C₄H₉NO in a chemical bath significantly increases the rate of deposition of a ZnS layer. In particular, to obtain a layer 20 nm thick, the bath optimized according to the invention divides the deposition time by 2.5 compared to conventional techniques, and by more than 5 compared to a deposition conducted under the same conditions without the organic additive.

In addition, it should be noted that the deposition conditions in the applicant's chemical bath are more efficient in materials saving and energy saving. This results from the lower concentrations of reagents, lower deposition temperature, and no preheating of the reagents.

The example described above can advantageously result in the creation of a complete photovoltaic device as shown in FIG. 4.

FIG. 4 schematically illustrates a thin-film solar cell comprising the same structural elements as those of FIG. 1. The represented device 400 further comprises a buffer layer 104 deposited on the absorber by CBD, as described above. Over the buffer layer 104 a first window layer 105, for example of intrinsic zinc oxide or ZnMgO, can be deposited by known techniques such as reactive sputtering, chemical vapor deposition, electrodeposition, CBD deposition, or ILGAR® deposition. A front electrical contact 106 can then be deposited. For example, it may be a layer of aluminum-doped zinc oxide ZnO.

Other advantages inherent to using the chemical bath described above for depositing a buffer layer are reflected in the performance of the photovoltaic devices obtained.

Table 2 compares the technical characteristics of solar cells such as the solar cell of FIG. 4, comprising a chalcopyrite-type CIGS absorber. A first cell comprises a ZnS buffer layer obtained under conventional deposition conditions as described above in relation to curve 301 of FIG. 3. A second cell comprises a ZnS buffer layer obtained by a CBD deposition process involving the bath of the invention, under conditions identical to those described in relation to curve 303 of FIG. 3. A third cell comprises a CdS buffer layer obtained by CBD under conventional deposition conditions.

TABLE 2
Performance comparison of three solar cells.

| | Efficiency | Form factor | | Jsc |
|---|---|---|---|---|
| Buffer layer | (%) | (%) | Voc (mV) | (mA/cm²) |
| ZnS | 13.7 | 71.8 | 611 | 31.3 |
| Conventional CBD | | | | |
| Standard deviation | +/−0.41 | +/−1.9 | +/−3.3 | +/−0.52 |
| ZnS | 14.4 | 74.6 | 622 | 30.8 |
| CBD with additive | | | | |
| Standard deviation | +/−0.18 | +/−0.46 | +/−2 | +/−0.18 |
| CdS | 13.8 | 73.7 | 619 | 30.1 |
| Conventional CBD | | | | |
| Standard deviation | +/−0.13 | +/−0.36 | +/−4.6 | +/−0.15 |

Each cell of Table 2 has a surface area of 5×5 cm² and a buffer layer 20 nm thick.

The columns in Table 2 represent four parameters for each of the three solar cells. The first column represents the conversion efficiency of the solar cell. The second column represents the form factor of each cell, providing an indication of the quality of the interface between buffer layer and absorber. The third column represents an open circuit voltage Voc. The higher this voltage, the better the electrical properties of the cell. The fourth column represents the short-circuit current Jsc. The higher this current, the better the electrical properties of the cell.

For each cell of Table 2, and for each parameter, the standard deviation of the corresponding value is indicated. This information provides an estimate of the homogeneity of the cell. The more a parameter varies within the cell, the higher the associated standard deviation. Such instability is indicative of structural defects in the cell, and all the more so in the buffer layer which is the only layer presenting substantial differences between the three compared cells.

It is apparent from the values of Table 2 that the cell having a ZnS buffer layer formed by the CBD deposition method developed in the context of the invention has a homogeneity that is superior to the other cells. In particular, it has a higher homogeneity than the cell having a ZnS layer formed by conventional CBD deposition.

Moreover, the cell produced by the method of the invention has a conversion efficiency that is greater than that of the other cells, as well as improved electrical properties.

The form factor of the cell obtained by the method of the invention is comparable to that of cells having a CdS buffer layer. Nevertheless, the overall homogeneity of the cell created by CBD deposition with the addition of morpholine is better. Therefore the deposition method with the addition of morpholine may be well suited to the creation of photosensitive cells of large surface area, or more generally to the creation of layers comprising metal and sulfur in industrial settings.

Observation by electron microscope has confirmed these observations concerning the structural quality of the deposition obtained by implementing the method of the invention.

The chemical bath developed, and the method that uses it to create a buffer layer, allow obtaining under adapted deposition conditions a buffer layer of a non-toxic material, for example cadmium-free.

The improved electrical and optical properties of the zinc sulfide and oxysulfide buffer layers were analyzed by calculating the quantum efficiency of the layer, in comparison to that of a CdS buffer layer.

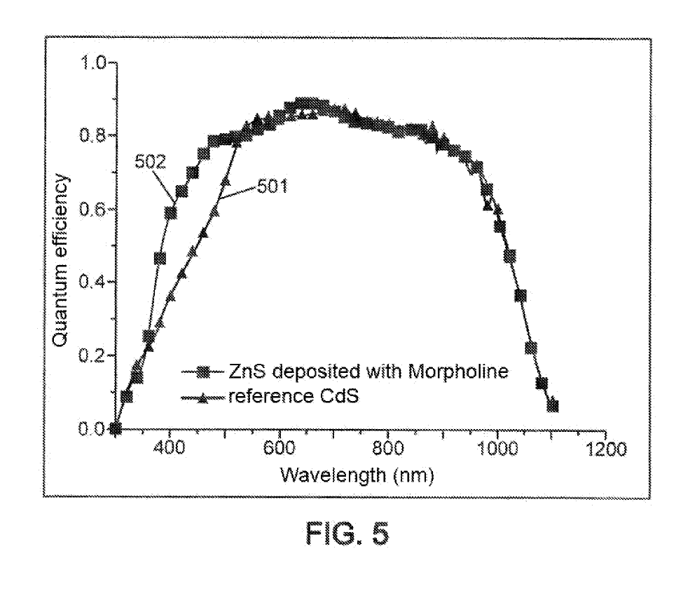

FIG. 5 shows a graph comparing the quantum efficiency between 300 nm and 1100 nm of a ZnS buffer layer, represented by curve 502, with that of a CdS buffer layer, represented by curve 501. Quantum efficiency is a parameter that represents the ratio between the amount of electrons produced and the amount of photons received by the photosensitive device.

It is apparent in FIG. 5 that a ZnS buffer layer allows better light conversion at wavelengths below 500 nm. This gain in current can be explained by a greater light transmission coefficient in ZnS at these wavelengths in comparison to CdS. This optical property is itself the result of the band structure of the material, which has a higher energy band gap than CdS.

The present invention is not limited to the embodiments described above by way of example; it also extends to other variants. Indeed, the bath described above and the method using this bath to produce a thin layer comprising metal and sulfur can be implemented in different configurations which all benefit from the gains in deposition rate and in quality of the obtained layer that are described above.

The concentrations of the various components of the reaction mixture 50 are therefore adjustable. For the sake of economy, it is preferable to reduce the concentration of reagents. However, reduced concentrations tend to increase the time required to produce a thin layer of a given thickness. The examples described above correspond to a compromise between concentration and reaction rate. It is possible to use other concentrations and other temperatures to meet a different need. It may be of interest, for example, to adjust the concentrations and temperatures to deposit a thin layer of a given thickness within a fixed time constraint. Indeed, due to the generally increased deposition rate, it is possible to use CBD deposition with morpholine as an additive to achieve layers more than 150 nm thick within a reasonable time, for example under an hour.

By increasing the deposition rate, it is possible to have the reaction mixture at a low temperature. Compared to conventional deposition techniques which generally involve temperatures of around 70° C., the invention allows obtaining a deposit in less than 15 minutes even when the temperature is below 60° C., for example down to 40° C.

The compromise between deposition rate and concentration of the reagents can be considered to be satisfactory for a concentration of metal salt between 0.01 mol/L and 1 mol/L, a concentration of sulfur precursor between 0.05 mol/L and 1 mol/L, a morpholine concentration between 0.001 mol/L and 10 mol/L, and an ammonia concentration between 0.1 mol/L and 10 mol/L.

However, the bath and the method that uses it can be envisaged without the addition of ammonia. It is possible, for example, to substitute another compound of basic pH, or a compound of pKa greater than 7, or to eliminate it from the bath. By eliminating this reagent, the CBD deposition process costs even less to implement, without negatively impacting the speed or quality of the deposition.

At a minimum, the reaction mixture of the chemical bath may contain only morpholine, sulfur precursor, and a metal salt. Beyond these basic components, the composition of the reaction mixture may differ from what is detailed above.

In particular, it is possible to use other morpholine-based compounds comprising shorter or longer functional groups. Advantageously, this compound gives the solution a basic pH in order to ensure hydrolysis of the sulfur precursor.

The thiourea may also be replaced by other sulfur precursors, preferably having equivalent chemical properties.

Aside from zinc sulfate, the metal salt may be replaced by zinc chloride or acetate for the same applications as those described above. The zinc acetate may be anhydrous or hydrated, for example of formula Zn[CH₃COOH]₂. An indium- or cadmium-based salt may also be suitable for the metal salt when creating buffer layers on photosensitive devices.

Furthermore, as the deposition of a layer of sulfur and zinc occurs in an aqueous medium, oxygen may be incorporated into the deposited layers to form a zinc oxysulfide of Zn(S,O) or Zn(S,O,OH) type. Similarly, it is possible to incorporate oxygen into a layer comprising another metal element such as indium, to form an indium oxysulfide of Inₓ(S,O)_{y} or Inₓ(S,O,OH)₅, type. Other elements of groups IIB and IIIA of the periodic table may also be considered for the metal, however, due to their chemical properties similar to those of zinc, indium, or cadmium.

As mentioned above, it is possible to apply the method described above in contexts other than deposition of a buffer layer on a photosensitive cell absorber. Indeed, the invention has also been tested successfully on other deposition surfaces such as glass, a semiconductor substrate, and a metal.

More generally, the invention described above optimizes a chemical bath for the deposition of a thin layer comprising sulfur and a metal. This optimization increases the deposition rate while improving the structural quality of the layer obtained, and saves materials and energy. In addition, the invention has the advantage of being compatible with existing chemical baths for CBD chemical deposition, and offers an advantageous solution for industrial scale CBD deposition on large surface areas.

1. A chemical bath for depositing a layer based on at least metal and sulfur, the chemical bath comprising, in a solution:
a metal salt comprising a metal selected from among at least one of the elements of groups IIB and IIIA of the periodic table; and
a sulfur precursor;
wherein the chemical bath further comprises a morpholine compound.

2. The chemical bath according to claim 1, wherein said morpholine compound has an amine function and an ether function acting in the chemical bath as a complexing agent.

3. The chemical bath according to claim 1, wherein the morpholine compound is of chemical formula C₄H₉NO.

4. The chemical bath according to claim 1, wherein a concentration between 0.001 mol/L and 10 mol/L of morpholine is provided in the chemical bath, for a concentration between 0.05 mol/L and 1 mol/L of sulfur precursor.

5. The chemical bath according to claim 4, wherein the metal salt is in a solution selected from among: zinc sulfate, zinc acetate, and zinc chloride, at a concentration between 0.01 mol/L and 1 mol/L.

6. The chemical bath according to claim 4, further comprising an ammonia solution at a concentration of less than 10 mol/L.

7. The chemical bath according to claim 1, wherein it contains no ammonia solution.

8. The chemical bath according to claim 1, wherein the sulfur precursor compound is in a solution of thiourea CS(NH₂)₂.

9. The chemical bath according to claim 1, wherein the metal is an element from column IIB.

10. The chemical bath according to claim 9, wherein the metal is zinc.

11. A method for chemically depositing a layer based on at least metal and sulfur, comprising:
depositing, in a solution in a chemical bath, a metal salt comprising a metal selected from among at least one of the elements of groups IIB and IIIA of the periodic table; and
depositing, in the solution in the chemical bath, a sulfur precursor; wherein the method further comprises providing a morpholine compound in said bath.

12. The method of claim 11, wherein the layer is based on a metal sulfide.

13. The method of claim 11, wherein the layer is based on a metal oxysulfide.

14. The method of claim 11, wherein the temperature of the chemical bath during deposition is between 40° C. and 100° C.

15. The method of claim 11, further comprising depositing the layer based on metal and sulfur on a layer having photovoltaic properties, said layer having photovoltaic properties forming the absorber of a thin-film solar cell.

16. The method of claim 15, wherein the absorber is based on a chalcopyrite compound among Cu(In,Ga)(S,Se)₂, Cu₂(Zn, Sn)(S, Se)₄, and their derivatives.
